(19) United States
(12) Patent Application Publication
(10) Pub. No.: US 2019/0149091 A1
(43) Pub. Date: May 16, 2019

(54) VIBRATOR GROUP MANUFACTURING METHOD AND OSCILLATOR MANUFACTURING METHOD

(71) Applicant: SEIKO EPSON CORPORATION, Tokyo (JP)

(72) Inventors: Koji HOSAKA, MINAMIMINOWA-MURA (JP); Atsushi MATSUO, SHIOJIRI-SHI (JP)

(73) Assignee: SEIKO EPSON CORPORATION, Tokyo (JP)

(21) Appl. No.: 16/185,878

(22) Filed: Nov. 9, 2018

(30) Foreign Application Priority Data
Nov. 10, 2017 (JP) 2017-217391

(51) Int. Cl. H03B 5/32; H01L 41/09; H01L 41/25; H01L 41/053; H01L 21/66; H01L 27/20

(52) U.S. Cl. CPC H03B 5/32; H01L 41/09; H01L 27/20; H01L 41/053; H01L 22/14; H01L 41/25

(57) ABSTRACT

A vibrator group manufacturing method includes measuring resonance frequencies of first to n-th vibrators with respect to a vibrator group including the first to n-th vibrators arranged in a matrix, n being an integer of 2 or greater, and storing attachment information of the vibrator group in a storage device, the attachment information including identification information imparted to the vibrator group, pieces of first to n-th positional information indicating positions of the first to n-th vibrators, and pieces of first to n-th characteristic information based on measurement results of the resonance frequencies of the first to n-th vibrators.

### BACKGROUND

### 1. Technical Field

The present invention relates to a vibrator group manufacturing method and an oscillator manufacturing method.

### 2. Related Art

Oscillators oscillating vibrators such as quartz crystal vibrators and outputting signals having desired frequencies have been widely used in various electronic apparatuses and systems. In general, vibrator manufacturers manufacture vibrators, perform characteristic inspection in an individual state, and then store the vibrators individually to provide the vibrators to oscillator manufacturers. Since the characteristics of the vibrators are individually different, it is desired that the vibrator manufacturers provide characteristic information for each vibrator and the oscillator manufacturers adjust the frequency of an oscillator using the characteristic information for each vibrator in order to realize oscillators with high frequency accuracy at low cost.

JP-A-2002-173106 discloses a method of supplying electronic components having different electrical characteristics among individuals. In the method, a packing container corresponds to each electronic component, and a data code having electrical characteristics printed thereon is stored together with the electronic component. According to this method, the data code having electrical characteristics printed thereon is stored together with the electronic component, and thus it is possible to accurately supply information regarding the electrical characteristics of the electronic component.

However, in the method disclosed in JP-A-2002-173106, it is necessary to add the data code to the packing container for each electronic component, and thus it is costly and difficult to reduce cost. Further, the method disclosed in JP-A-2002-173106 is targeted for a supply configuration in which electronic components are stored by being arranged in a row in a carrier tape wound around a reel, and thus it is possible to print a code indicating characteristic information in the vicinity of each electronic component on the carrier tape even when the electronic component is made small. However, in a case of a supply configuration in which a vibrator group is divided into individual pieces and the individual pieces are arranged in a matrix on a wafer or a supply configuration in which individual pieces obtained by dividing a vibrator group are arranged in a matrix on a tray, it is extremely difficult to secure a space for printing a code indicating characteristic information in the vicinity of each vibrator.

### SUMMARY

An advantage of some aspects of the invention is to provide a vibrator group manufacturing method for realizing a vibrator group usable for the manufacture of a high-accuracy vibration device at low cost, and an oscillator manufacturing method for realizing a high-accuracy oscillator at low cost.

The invention can be implemented as the following forms or application examples.

### Application Example 1

A vibrator group manufacturing method according to this application example includes measuring resonance frequencies of first to n-th vibrators with respect to a vibrator group including the first to n-th vibrators arranged in a matrix, n being an integer of 2 or greater, and storing attachment information of the vibrator group in a storage device, the attachment information including identification information imparted to the vibrator group, pieces of first to n-th positional information indicating positions of the first to n-th vibrators, and pieces of first to n-th characteristic information based on measurement results of the resonance frequencies of the first to n-th vibrators.

According to the vibrator group manufacturing method of this application example, the vibrator group including vibrators arranged in a matrix is formed, and the attachment information including the positional information and the characteristic information of the vibrators constituting the vibrator group is stored in the storage device. Thus, a code indicating the characteristic information is not required to be printed on each vibrator or in the vicinity of the vibrator, and thus it is possible to manufacture the vibrator group at low cost. In addition, when a vibration device such as an oscillator or a vibration type sensor is manufactured using the vibrator included in the vibrator group manufactured by the vibrator group manufacturing method according to this application example, it is possible to acquire the attachment information of the vibrator group and to adjust the vibration device with a high level of accuracy using the characteristic information regarding the vibrator selected based on the positional information. Therefore, according to the vibrator group manufacturing method of this application example, it is possible to realize the vibrator group usable for the manufacture of a high-accuracy vibration device at low cost.

### Application Example 2

In the vibrator group manufacturing method according to the application example, the attachment information stored in the storage device maybe accessible through a communication network, and an access code for accessing the attachment information may be provided in a vibrator group holding member that holds the vibrator group.

According to the vibrator group manufacturing method of this application example, an access code for accessing the attachment information of the vibrator group through the communication network is provided in the vibrator group holding member, and thus it is not necessary to provide a plurality of codes indicating the characteristic information of the vibrators in the vibrator group holding member. Further, the access code has a smaller amount of information than the code indicating the characteristic information of the vibrators, and thus space required to provide the access code in the vibrator group holding member may be small. Therefore, according to the vibrator group manufacturing method of this application example, even when vibrator group includes the vibrators arranged in a matrix and the vibrators are made small, a space for providing the access code in the vibrator group holding member can be easily secured, and thus it is possible to manufacture the vibrator group at low cost.

### Application Example 3

The vibrator group manufacturing method according to the application example may further include mounting the storage device on a vibrator group holding member that holds the vibrator group.

According to the vibrator group manufacturing method of this application example, the storage device storing the attachment information of the vibrator group is mounted on the vibrator group holding member, and thus it is not necessary to provide a plurality of codes indicating the characteristic information of the vibrators in the vibrator group holding member. Therefore, according to the vibrator group manufacturing method of this application example, even when the vibrator group is arranged in a matrix and the vibrators are made small, a space for mounting the storage device in the vibrator group holding member can be easily secured, and thus it is possible to manufacture the vibrator group at low cost.

### Application Example 4

In the vibrator group manufacturing method according to the application example, the pieces of first to n-th characteristic information may include measurement results of resonance frequencies of the first to n-th vibrators at a predetermined temperature.

The predetermined temperature is, for example, a reference temperature (a temperature at which a frequency deviation is set to 0) in a frequency temperature characteristic of the vibrator, and a difference between a resonance frequency at each temperature and a resonance frequency at the predetermined temperature is set to be a frequency deviation at each temperature. The predetermined temperature may be, for example, any temperature included in a temperature range of 25° C.±5° C. (20° C. to 30° C.)

According to the vibrator group manufacturing method of this application example, the attachment information of the vibrator group includes measurement results of resonance frequencies of the vibrators at the predetermined temperature. Thus, when the vibration device is manufactured using the vibrators included in the vibrator group, it is possible to adjust the oscillation frequency of the vibration device at the predetermined temperature with a high level of accuracy using the measurement results of the resonance frequencies of the vibrators at the predetermined temperature.

### Application Example 5

The vibrator group manufacturing method according to the application example may further include measuring resonance frequencies of the first to n-th vibrators at a plurality of different temperatures, and the first to n-th characteristic information may include information based on temperature dependence of the resonance frequencies of the first to n-th vibrators.

According to the vibrator group manufacturing method of this application example, the attachment information of the vibrator group includes the information based on the temperature dependence of the resonance frequencies of the vibrators. Thus, when the vibration device is manufactured using the vibrators included in the vibrator group, it is possible to adjust a frequency temperature characteristic of the vibration device with a high level of accuracy using the information based on the temperature dependence of the resonance frequencies of the vibrators.

### Application Example 6

The vibrator group manufacturing method according to the application example may further include preparing a vibration piece mounting substrate, first to n-th vibration pieces, and a sealing substrate, mounting the first to n-th vibration pieces on the vibration piece mounting substrate in a matrix, bonding the sealing substrate to the vibration piece mounting substrate on which the first to n-th vibration pieces are mounted, and cutting the vibration piece mounting substrate having the sealing substrate bonded thereto to form the vibrator group including the first to n-th vibrators respectively including the first to n-th vibration pieces.

According to the vibrator group manufacturing method of this application example, since it is easy to assemble the vibrators and the vibrator group includes vibrators arranged in a matrix in a state of being divided into individual pieces, it is not also necessary to rearrange the vibrators, and thus it is possible to manufacture the vibrator group at low cost.

### Application Example 7

An oscillator manufacturing method according to this application example includes preparing a vibrator group including first to n-th vibrators arranged in a matrix, and first to n-th integrated circuit devices, acquiring attachment information of the vibrator group which includes pieces of first to n-th positional information indicating positions of the first to n-th vibrators and pieces of first to n-th characteristic information based on measurement results of resonance frequencies of the first to n-th vibrators, selecting the k-th vibrator from the vibrator group to integrate the k-th vibrator and the k-th integrated circuit device with each other, k being an integer of 1 to n, and selecting the k-th characteristic information based on the k-th positional information to perform frequency adjustment of an output signal of the k-th integrated circuit device based on the k-th characteristic information.

According to the oscillator manufacturing method of this application example, it is possible to integrate the vibrators included in the vibrator group and the integrated circuit devices with each other, and to adjust the vibration device with a high level of accuracy using characteristic information selected based on positional information of the vibrators which is included in the attachment information of the vibrator group. In addition, according to the oscillator manufacturing method of this application example, the attachment information including the positional information and the characteristic information of the vibrators arranged in a matrix and constituting the vibrator group is acquired, and thus it is not necessary to use a more expensive vibrator group in which a code indicating the characteristic information is printed on each vibrator or in the vicinity of the vibrator. Therefore, according to the oscillator manufacturing method of this application example, it is possible to realize a high-accuracy oscillator at low cost.

### Application Example 8

In the oscillator manufacturing method according to the application example, the attachment information may be stored in a storage device accessible through a communication network, and the attachment information stored in the storage device may be acquired using an access code provided in a vibrator group holding member that holds the vibrator group.

According to the oscillator manufacturing method of this application example, the attachment information of the vibrator group is acquired through the communication network using the access code provided in the vibrator group holding member, and thus it is not necessary to use a more expensive vibrator group in which a plurality of codes indicating the characteristic information of the vibrators are provided in the vibrator group holding member. Therefore, according to the oscillator manufacturing method of this application example, it is possible to realize a high-accuracy oscillator at low cost.

### Application Example 9

In the oscillator manufacturing method according to the application example, the attachment information may be stored in a storage device mounted on a vibrator group holding member that holds the vibrator group.

According to the oscillator manufacturing method of this application example, the attachment information of the vibrator group can be acquired from the storage device mounted on the vibrator group holding member, and thus it is not necessary to use a more expensive vibrator group in which a plurality of codes indicating the characteristic information of the vibrators are provided in the vibrator group holding member. Therefore, according to the oscillator manufacturing method of this application example, it is possible to realize a high-accuracy oscillator at low cost.

### BRIEF DESCRIPTION OF THE DRAWINGS

The invention will be described with reference to the accompanying drawings, wherein like numbers reference like elements.

FIG. 1 is a flowchart illustrating an example of a procedure of a vibrator group manufacturing method according to a first exemplary embodiment.

FIG. 2 is a flowchart illustrating an example of a procedure of a vibrator group forming process.

FIG. 3 is a perspective view of a vibration piece mounting substrate, and a side view of a broken line portion thereof.

FIG. 4 is a perspective view of a sealing substrate, and a side view (perspective side view) of a broken line portion thereof.

FIG. 5 is a perspective view of a vibration piece mounting substrate on which some of first to n-th vibration pieces are mounted, and a side view (perspective side view) of a broken line portion thereof.

FIG. 6 is a perspective view of a vibration piece mounting substrate to which a sealing substrate is bonded, and a side view (perspective side view) of a broken line portion thereof.

FIG. 7 is a perspective view of a vibrator group, and a side view (perspective side view) of a broken line portion thereof.

FIG. 8 is a flowchart illustrating an example of a procedure of a characteristic information creating process.

FIG. 9 is a diagram illustrating an equivalent circuit of a vibrator.

FIG. 10 is a diagram illustrating an example of the positions of first to n-th vibrators within a vibrator group 1.

FIG. 11 is a diagram illustrating an example of attachment information to be attached to a vibrator group.

FIG. 12 is a diagram illustrating an attachment information storage process.

FIG. 13 is a diagram illustrating an access code addition process.

FIG. 14 is a flowchart illustrating an example of a procedure of an oscillator manufacturing method according to the first exemplary embodiment.

FIG. 15 is a diagram illustrating a process of acquiring attachment information of a vibrator group.

FIG. 16 is a flowchart illustrating an example of a procedure of a vibrator group manufacturing method according to a second exemplary embodiment.

FIG. 17 is a diagram illustrating a storage device mounting process.

FIG. 18 is a flowchart illustrating an example of a procedure of an oscillator manufacturing method according to the second exemplary embodiment.

### DESCRIPTION OF EXEMPLARY EMBODIMENTS

Hereinafter, preferred exemplary embodiments of the invention will be described in detail with reference to the accompanying drawings. Meanwhile, the exemplary embodiments to be described below do not unduly limit the contents of the invention described in the appended claims. In addition, all configurations to be described below are not limited to being essential constituent conditions of the invention.

### 1. First Exemplary Embodiment

### 1-1. Vibrator Group Manufacturing Method

### Procedure of Vibrator Group Manufacturing Method

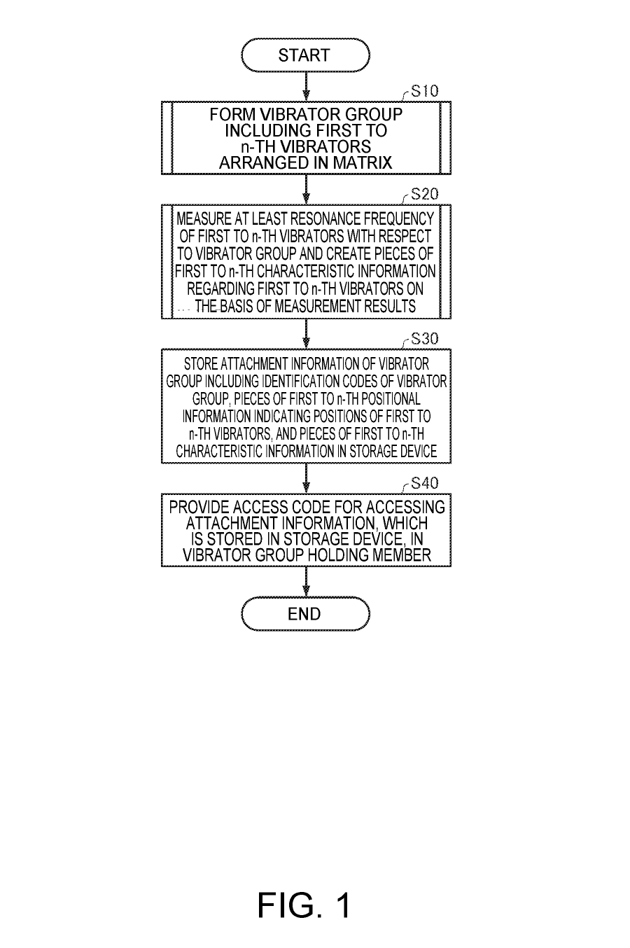

FIG. 1 is a flowchart illustrating an example of a procedure of a vibrator group manufacturing method according to a first exemplary embodiment. For example, a vibrator manufacturer manufactures a vibrator group 1 in accordance with the procedure of FIG. 1. As illustrated in FIG. 1, in this exemplary embodiment, first, a process (vibrator group forming process) S10 of forming the vibrator group 1 (see FIG. 7 to be described later) including first to n-th vibrators 10 arranged in a matrix is performed, n being an integer of 2 or greater. The vibrator group forming process S10 is realized by various methods, and a specific example thereof will be described later.

Next, a process (characteristic information creating process) S20 of measuring at least a resonance frequency of the first to n-th vibrators 10 with respect to the vibrator group 1 (a vibrator group including the first to n-th vibrators 10 arranged in a matrix) obtained in the vibrator group forming process S10, and creating pieces of first to n-th characteristic information regarding the first to n-th vibrators 10 based on measurement results is performed. The characteristic information creating process S20 is realized by various methods, and a specific example thereof will be described later.

Next, a process (attachment information storage process) S30 of storing attachment information of the vibrator group 1 in a storage device 301 (see FIG. 12 to be described later) is performed. The attachment information includes attachment information (information to be attached to the vibrator group 1) including identification information of the vibrator group 1 (identification information added to the vibrator group 1) obtained in the vibrator group forming process S10, pieces of first to n-th positional information indicating the positions (positions within the vibrator group) of the first to n-th vibrators 10, and the pieces of first to n-th characteristic information (pieces of first to n-th characteristic information based on the measurement results on the resonance frequencies of the first to n-th vibrators 10) obtained in the characteristic information creating process S20. In this exemplary embodiment, the attachment information of the vibrator group 1 stored in the storage device 301 is accessible through a communication network 100 (see FIG. 12 to be described later).

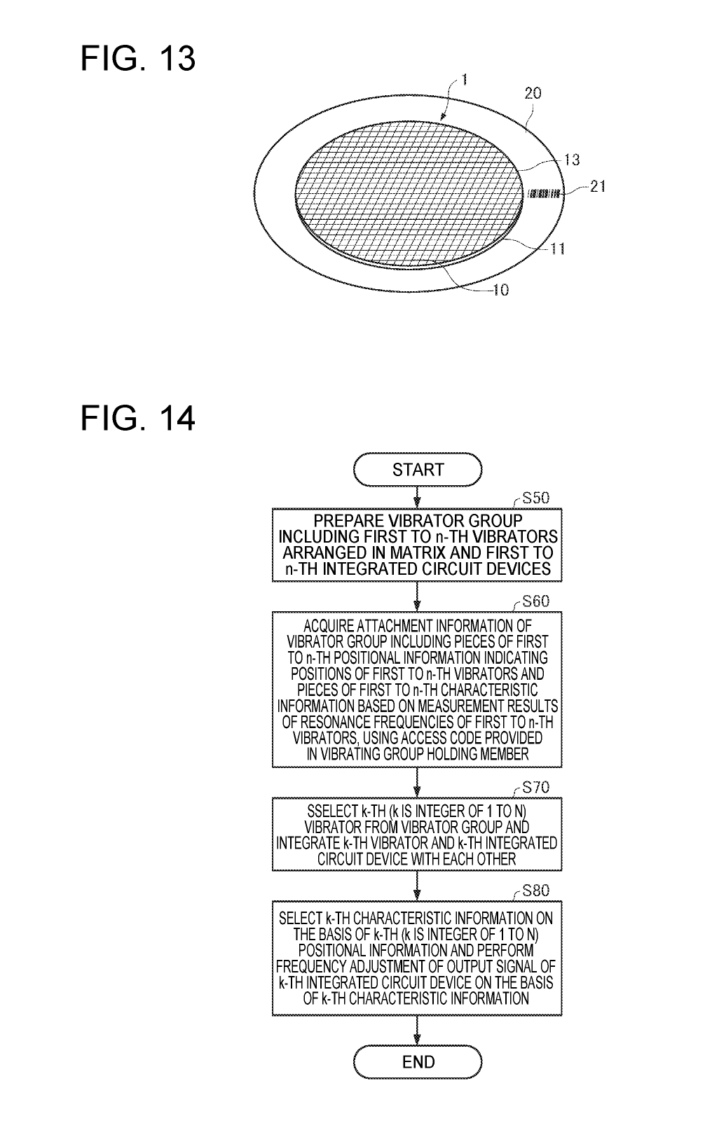

Finally, a process (access code addition process) S40 of providing an access code 21 (see FIG. 13 to be described later) for accessing the attachment information, which is stored in the storage device 301 in the attachment information storage process S30, in a vibrator group holding member 20 (see FIGS. 7 and 13 to be described later) holding the vibrator group obtained in the vibrator group forming process S10 is performed.

Meanwhile, the order of the attachment information storage process S30 and the order of the access code addition process S40 may be changed.

### Procedure of Vibrator Group Forming Process

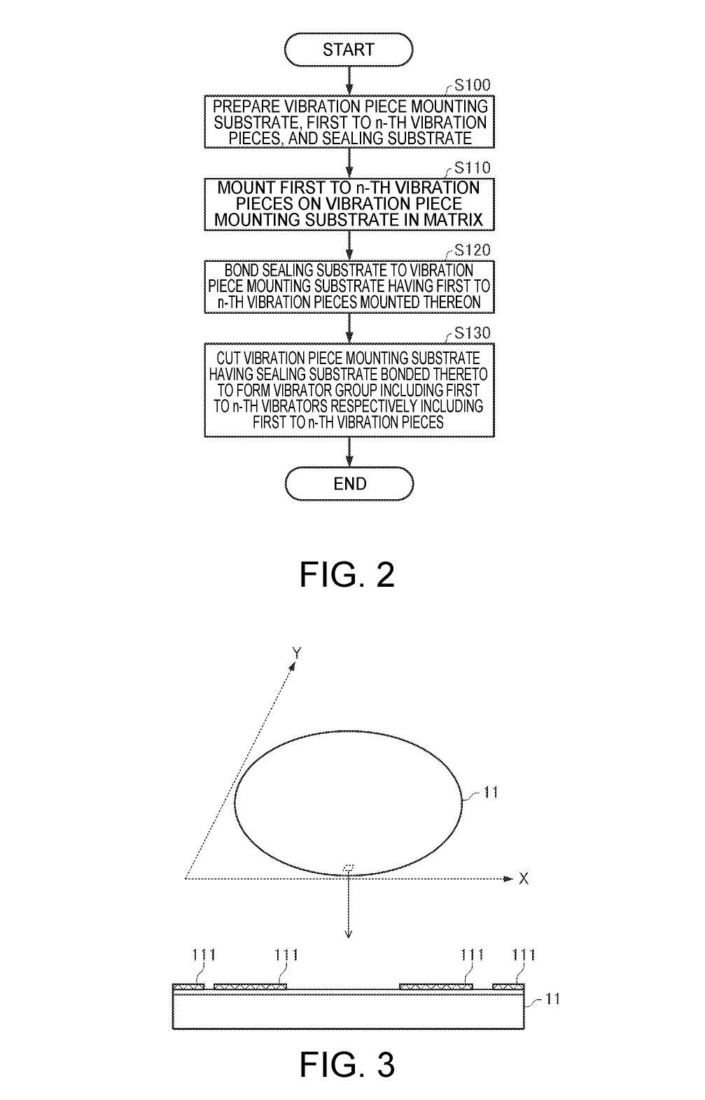

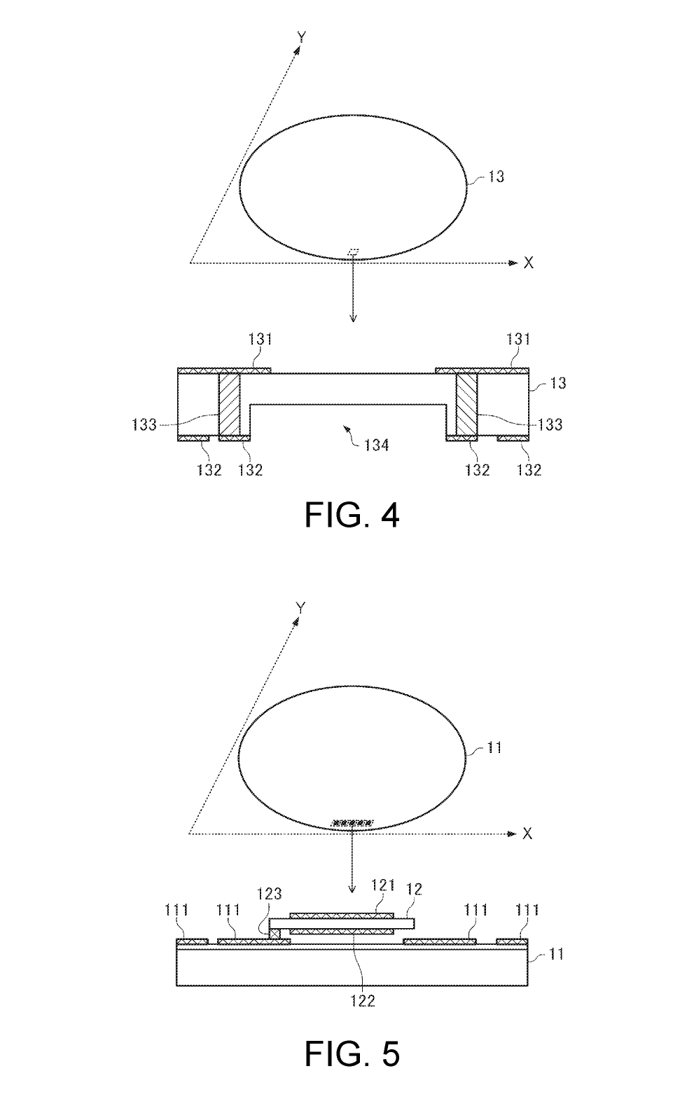

FIG. 2 is a flowchart illustrating an example of a procedure of the vibrator group forming process S10 of FIG. 1. In the example of FIG. 2, first, a vibration piece mounting substrate 11, first to n-th vibration pieces 12, and a sealing substrate 13 are prepared (step S100). FIG. 3 is a perspective view of the vibration piece mounting substrate 11 and a side view of a broken line portion thereof. As illustrated in the perspective view of FIG. 3, the vibration piece mounting substrate 11 is a circular planar plate, and is formed of, for example, silicon (Si) as a material. As illustrated in the side view of FIG. 3, a plurality of electrodes 111 are provided on the upper surface of the vibration piece mounting substrate 11. The vibration piece mounting substrate 11 is configured such that the structure of the broken line portion illustrated in FIG. 3 is repeated in a matrix in the X-axis direction and the Y-axis direction perpendicular to each other. In addition, FIG. 4 is a perspective view of the sealing substrate 13 and a side view (perspective side view) of a broken line portion thereof. As illustrated in the perspective view of FIG. 4, the sealing substrate 13 is a circular planar plate, and is formed of, for example, glass (borosilicate glass or the like excellent in heat resistance and chemical resistance) as a material. As illustrated in the side view of FIG. 4, two electrodes 131 are provided on the upper surface of the sealing substrate 13, and a plurality of electrodes 132 are provided on the lower surface of the sealing substrate 13. The two electrodes 131 are electrically connected to the electrodes 132 different from each other through via holes 133. In addition, a concave portion 134 for forming a space for accommodating the vibration piece 12 is formed in the lower surface of the sealing substrate 13. The sealing substrate 13 is configured such that the structure of the broken line portion illustrated in FIG. 4 is repeated in a matrix in the X-axis direction and the Y-axis direction.

Next, the first to n-th vibration pieces 12 are mounted on the vibration piece mounting substrate 11 in a matrix (step S110). FIG. 5 is a perspective view of the vibration piece mounting substrate 11 on which some of the first to n-th vibration pieces 12 are mounted, and a side view (perspective side view) of a broken line portion thereof. The first to n-th vibration pieces 12 have the same structure, and are formed of, for example, quartz crystal as a material. As illustrated in the side view of FIG. 5, each of the vibration pieces 12 is configured such that an electrode 121 is provided on the upper surface thereof and an electrode 122 and two electrodes 123 are provided on the lower surface thereof (in FIG. 5, the two electrodes 123 are superimposed on each other). One electrode 123 is electrically connected to the electrode 121 by a wiring pattern, not shown in the drawing, which is provided in the vibration piece 12, and the other electrode 123 is electrically connected to the electrode 122 by the wiring pattern provided in the vibration piece 12. The two electrodes 123 of each of the vibration pieces 12 are electrically connected to different electrodes 111 of the vibration piece mounting substrate 11 by step S110.

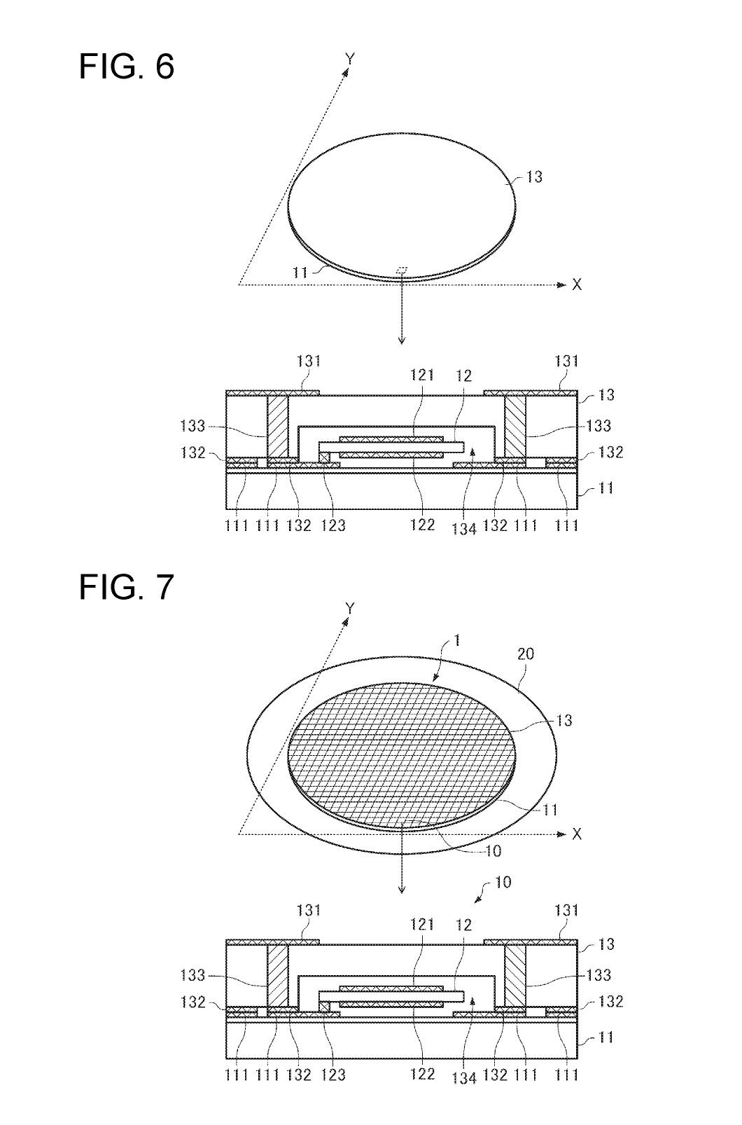

Next, the sealing substrate 13 is bonded to the vibration piece mounting substrate 11 having the first to n-th vibration pieces 12 mounted thereon which is obtained by step S110 (step S120). FIG. 6 is a perspective view of the vibration piece mounting substrate 11 to which the sealing substrate 13 is bonded, and a side view (perspective side view) of a broken line portion thereof. As illustrated in the perspective view of FIG. 6, the vibration piece mounting substrate 11 and the sealing substrate 13 have the same size, and are bonded to each other through, for example, anodic bonding so that mutual outer edge portions are superimposed on each other (mutual X-axes and Y-axes are consistent with each other). As illustrated in the side view of FIG. 6, the electrodes 111 of the vibration piece mounting substrate 11 and the electrodes 132 of the sealing substrate 13 are electrically connected to each other, and the vibration pieces 12 are accommodated in an accommodation space constituted by the concave portion 134 formed in the lower surface of the sealing substrate 13 and the upper surface of the vibration piece mounting substrate 11 by step S120.

Finally, the vibration piece mounting substrate 11 having the sealing substrate 13 bonded thereto, which is obtained by step S120, is cut, and the vibrator group 1 including the first to n-th vibrators 10 respectively including the first to n-th vibration pieces 12 is formed (step S130). FIG. 7 is a perspective view of the vibrator group 1 including the first to n-th vibrators 10, and a side view (perspective side view) of a broken line portion thereof. In step S130, the vibration piece mounting substrate 11 having the sealing substrate 13 bonded thereto is cut (diced) in a state of being held by the vibrator group holding member 20, and the vibrator group 1 including the first to n-th vibrators 10 disposed in a matrix in the X-axis direction and the Y-axis direction is formed as illustrated in FIG. 6. The vibrator group holding member 20 is a circular member having a size larger than that of the vibration piece mounting substrate 11, and is, for example, a dicing tape (also referred to as a “wafer tape”). In each of the first to n-th vibrators 10 constituting the vibrator group 1 formed by step S130, driving voltages having opposite phases are applied to the electrode 121 and the electrode 122 of the vibration piece 12 through the electrode 111 and the electrode 123, whereby thickness-shear vibration of the vibration piece 12 occurs.

Meanwhile, the structure of the vibrator 10 illustrated in FIG. 7 is just an example, and the vibrator 10 may be, for example, a Surface Acoustic Wave (SAW) resonator, or may be a piezoelectric vibrator, a Micro Electro Mechanical Systems (MEMS) vibrator, or the like other than a quartz crystal vibrator. In addition to quartz crystal, piezoelectric single crystals such as lithium tantalate and lithium niobate, piezoelectric materials such as piezoelectric ceramics, for example, lead zirconate titanate, silicon semiconductor materials, and the like can be used as the material of the vibration piece 12. As excitation means of the vibrator 10, excitation means based on a piezoelectric effect may be used, or electrostatic driving based on Coulomb force may be used.

### Procedure of Characteristic Information Creating Process

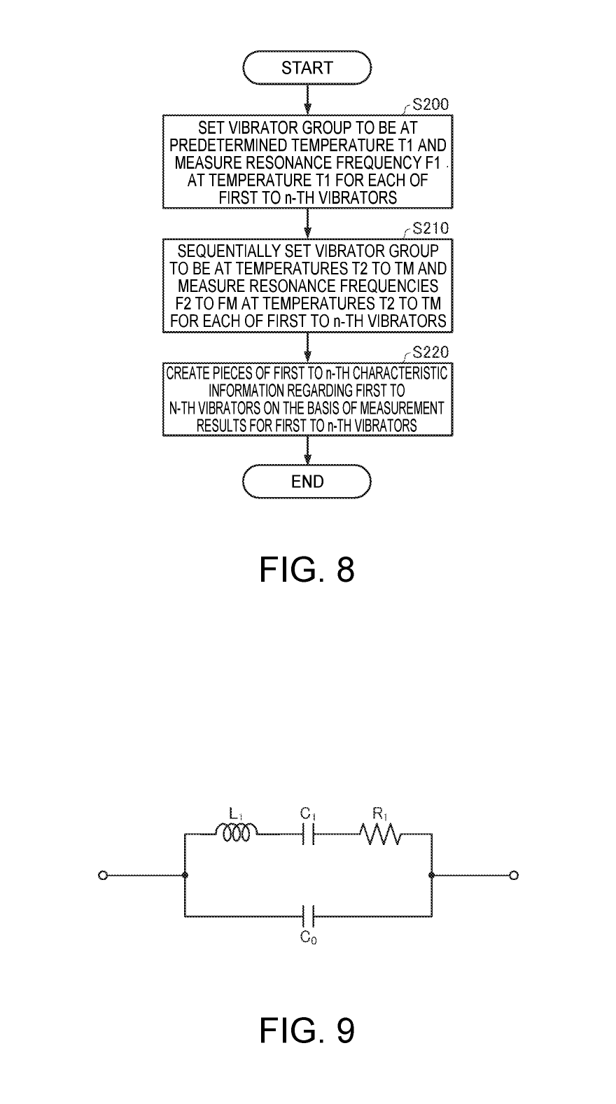

FIG. 8 is a flowchart illustrating an example of a procedure of the characteristic information creating process S20 of FIG. 1. In FIG. 8, the order of the processes may be appropriately changed.

In the example of FIG. 8, first, the vibrator group 1 formed in the vibrator group forming process (step S10 of FIG. 1) is set to be at a predetermined temperature T1, and a resonance frequency f1 at the temperature T1 is measured for each of the first to n-th vibrators 10 (step S200). For example, the temperature T1 is a reference temperature (a temperature at which a frequency deviation is set to 0) in a frequency temperature characteristic of the vibrator 10, and a difference between a resonance frequency at each temperature and a resonance frequency at the temperature T1 is set to be a frequency deviation at each temperature. For example, the temperature T1 maybe any temperature included in a temperature range of 25° C.±5° C. (20° C. to 30° C.). For example, the resonance frequency f1 maybe measured by measuring an equivalent circuit constant for each of the first to n-th vibrators 10 at the temperature T1 and calculating the resonance frequency f1 based on the measured values of the equivalent circuit constants. FIG. 9 illustrates an equivalent circuit of the vibrator 10. As illustrated in FIG. 9, examples of the equivalent circuit constants of the vibrator 10 include an equivalent series inductance L₁, an equivalent series capacitance C₁, an equivalent series resistance R₁, and a parallel capacitance C₀. For example, in step S200, the equivalent circuit constants C₀, C₁, R₁, and L₁ are measured for each of the first to n-th vibrators 10, and a resonance frequency f1 can be calculated by the following expression (1).

$$f 1 = \frac{1}{2 π \sqrt{{L}_{1} \cdot {C}_{1}}} \qquad ( 1 )$$

Meanwhile, the measurement of the equivalent circuit constants of the vibrator 10 can be performed by connecting, for example, a measurement device such as a network analyzer or an impedance analyzer to two electrodes 131 (see FIG. 7) of the vibrator 10.

Next, the vibrator group 1 is sequentially set to be at temperatures T2 to Tm (m≥2), and resonance frequencies f2 to fm at the temperatures T2 to Tm are measured for each of the first to n-th vibrators 10 (step S210). For example, the temperatures T2 to Tm are temperatures different from the temperature T1, and are different temperatures included in a temperature range in which the operation of the vibrator 10 is secured. As the number (m−1) of measurement temperatures in step S210 increases, a frequency temperature characteristic having high accuracy of the vibrator 10 is obtained. However, since a measurement time increases, m is appropriately selected according to the use of the vibrator 10. For example, similarly to step S200, also in step S210, it is possible to measure equivalent circuit constants C₀, C₁, R₁, and L₁ at each of the temperatures T2 to Tm for each of the first to n-th vibrators 10 and to calculate (measure) resonance frequencies f2 to fm by Expression (1).

Finally, pieces of first to n-th characteristic information regarding the first to n-th vibrators 10 are created based on the measurement results in steps S200 and S210 (step S220). In this exemplary embodiment, the pieces of first to n-th characteristic information include the measurement results in step S200, that is, the values of the resonance frequencies f1 to f2 of each of the first to n-th vibrators 10 at the temperature T1. In addition, the pieces of first to n-th characteristic information may include the measurement results in steps S200 and S210, that is, information based on temperature dependence of the resonance frequencies of the first to n-th vibrators 10 obtained from the values of the resonance frequencies f1 to f2 of the first to n-th vibrators 10 at a plurality of different temperatures T1 to Tm. For example, the information based on temperature dependence of the resonance frequencies of the first to n-th vibrators 10 may be the values of the resonance frequencies f1 to f2 of the first to n-th vibrators 10 at the temperatures T1 to Tm, or may be temperature compensation information regarding the first to n-th vibrators 10.

For example, the temperature compensation information regarding each of the vibrators 10 may include the values of coefficients α₁ to αₚ of Expression (2) calculated from the values of the resonance frequencies f1 to fm at the temperatures T1 to Tm by approximating a frequency temperature characteristic f(T) of the vibrator 10 by a p-th expression (2) with a temperature T as a variable, or may include a coefficient value of a correction expression for bringing the frequency temperature characteristic f(T) close to the resonance frequency f1 without depending on the temperature T.

f(T)=f1+α₁·(T−T1)+α₂·(T−T1)²+ . . . +αₚ·(T−T1)^{p} (2)

In addition, the pieces of first to n-th characteristic information may include the values of the equivalent circuit constants C₀, C₁, R₁, and L₁ of each of the first to n-th vibrators 10 at the temperature T1 measured in step S200. In addition, for example, the pieces of first to n-th characteristic information may include information for specifying Expression (3) of a load resonance frequency f_{L} with a load capacity C_{L} as a variable.

$${f}_{L} = f 1 \cdot ( \frac{{C}_{1}}{2 \cdot ( {C}_{0} + {C}_{L} )} + 1 ) \qquad ( 3 )$$

In addition, the pieces of first to n-th characteristic information may include Q values of the first to n-th vibrators 10. The Q value of the vibrator 10 is calculated by the following Expression (4).

$$Q = \frac{2 π \cdot f 1 \cdot {L}_{1}}{{R}_{1}} = \frac{1}{2 π \cdot f 1 \cdot {C}_{1} \cdot {R}_{1}} \qquad ( 4 )$$

Meanwhile, when information regarding the frequency temperature characteristics of the first to n-th vibrators 10 are not necessary, step S210 may be omitted.

### Attachment Information of Vibrator Group

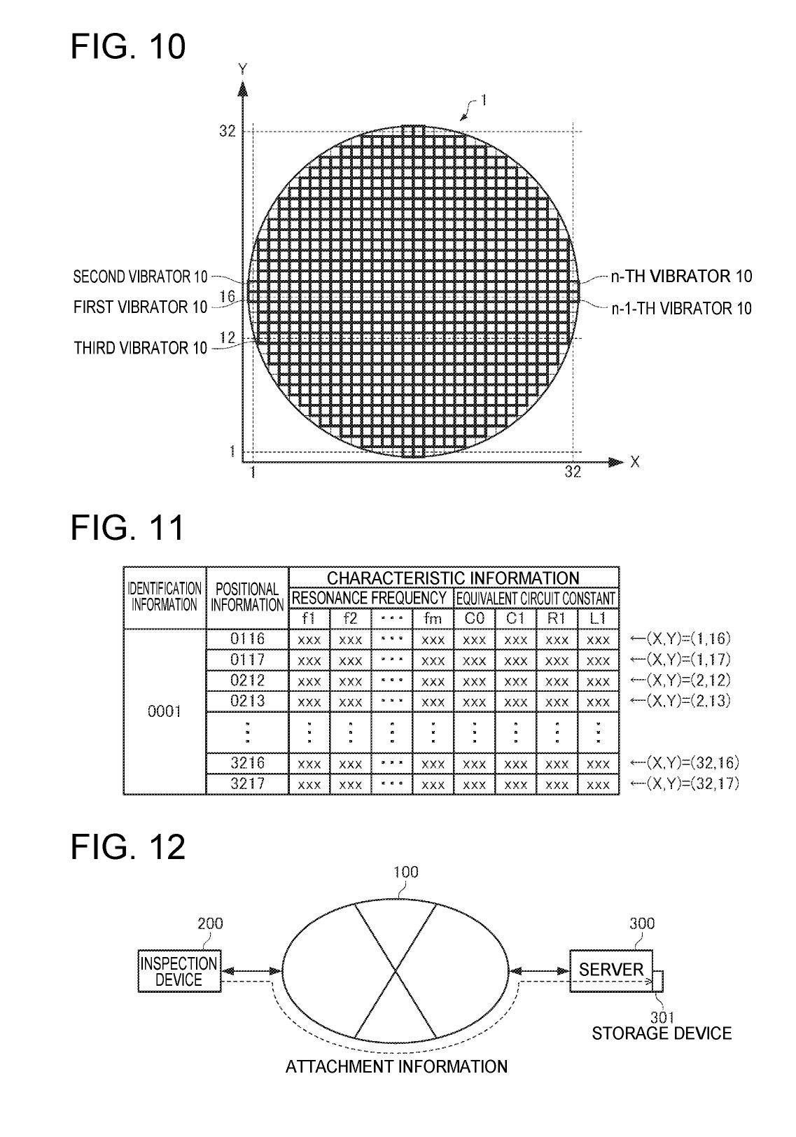

As described above, the vibrator group 1 including the first to n-th vibrators 10 arranged in a matrix in the X-axis direction and the Y-axis direction is formed by a vibrator group forming process (step S10 in FIG. 1 (steps S100 to S130 in FIG. 2)). Therefore, the positions of the first to n-th vibrators 10 within the vibrator group 1 are uniquely specified by XY coordinates. FIG. 10 illustrates an example of the positions (XY coordinates) of the first to n-th vibrators 10 within the vibrator group 1. FIG. 10 is a diagram when the vibrator group 1 is viewed in a plane view from above (the sealing substrate 13 side), and portions surrounded by heavy lines are equivalent to the first to n-th vibrators 10. In the example of FIG. 10, the first to n-th vibrators 10 are arranged in 32 columns in both the X-axis direction and the Y-axis direction in ascending order of an X coordinate and a Y coordinate by giving priority to the X coordinate. That is, the XY coordinates of the first vibrator 10 are (1,16), the XY coordinates of the second vibrator 10 are (1,17), the XY coordinates of the third vibrator 10 are (2,12), . . . , the XY coordinates of the n−1-th vibrator 10 are (32,16), and the XY coordinates of the n-th vibrator 10 are (32,17).

The pieces of first to n-th characteristic information created by the characteristic information creating process (step S20 in FIG. 1 (steps S200 to S220 in FIG. 8)) are associated with the pieces of first to n-th positional information for respectively specifying the positions (XY coordinates) of the first to n-th vibrators 10, and serve as a portion of the attachment information of the vibrator group 1.

FIG. 11 is a diagram illustrating an example of attachment information to be attached to the vibrator group 1 illustrated in FIG. 10. In the example of FIG. 11, the attachment information includes the identification information of the vibrator group 1, the pieces of first to n-th positional information respectively indicating the positions of the first to n-th vibrators 10 within the vibrator group 1, and the pieces of first to n-th characteristic information regarding the first to n-th vibrators 10. The identification information is information for identifying the vibrator group 1 from other vibrator groups 1, and a different code is allocated for each vibrator group 1. In the example of FIG. 11, a four-digit code “0001” is allocated as identification information. In the example of FIG. 11, a four-digit value of which the upper two digits are consistent with the X coordinate of the k-th vibrator 10 and the lower two digits are consistent with the Y coordinate of the k-th vibrator 10 is allocated as k-th positional information with respect to an integer k from 1 to n. For example, the value of the first positional information indicating the position (XY coordinates are (1,16)) of the first vibrator 10 is 0116, and the value of positional information indicating the position (XY coordinates are (32,17)) of the n-th vibrator 10 is 3217. In addition, the pieces of first to n-th characteristic information include the values of the resonance frequencies f1 to fm and the values of the equivalent circuit constants C₀, C₁, R₁, and L₁.

As illustrated in FIG. 12, attachment information of the vibrator group 1 is created, for example, by an inspection device 200, is transmitted to a server 300 connected to the communication network 100 through the communication network 100 (for example, the Internet or a Local Area Network (LAN)) in the attachment information storage process S30 of FIG. 1, and is stored in the storage device 301 provided in the server 300.

In addition, as illustrated in FIG. 13, in the access code addition process S40 of FIG. 1, an access code 21 for accessing the attachment information stored in the storage device 301 is provided in the vibrator group holding member 20 holding the vibrator group 1. For example, the access code 21 is a bar code, a two-dimensional code such as a QR code (registered trademark), a numeric string, a character string, or the like, and the access code 21 may be printed on the vibrator group holding member 20, or a seal having the access code 21 printed thereon may be attached to the vibrator group holding member 20.

In the above-described vibrator group manufacturing method of the first exemplary embodiment, the vibrator group 1 held by the vibrator group holding member 20 and including the first to n-th vibrators 10 arranged in a matrix is manufactured, and attachment information including the pieces of first to n-th positional information indicating the positions of the first to n-th vibrators 10 within the vibrator group 1 and the pieces of first to n-th characteristic information associated with the pieces of first to n-th positional information is created. In addition, the attachment information is stored in the storage device 301 through the communication network 100, and can be accessed using the access code 21 provided in the vibrator group holding member 20. Therefore, according to the vibrator group manufacturing method of the first exemplary embodiment, a code indicating characteristic information is not required to be printed on each vibrator 10 or in the vicinity of the vibrator, and thus it is possible to manufacture the vibrator group 1 at low cost. In addition, when a vibration device such as an oscillator or a vibration type sensor is manufactured using the vibrator 10 included in the vibrator group 1 manufactured by the vibrator group manufacturing method according to the first exemplary embodiment, it is possible to acquire the attachment information of the vibrator group 1 and to adjust the vibration device with a high level of accuracy using the characteristic information regarding the vibrator 10 selected based on the positional information. Therefore, according to the vibrator group manufacturing method of the first exemplary embodiment, it is possible to realize the vibrator group 1 usable for the manufacture of a high-accuracy vibration device at low cost.

In addition, the access code 21 has a smaller amount of information than that of a code indicating the characteristic information regarding each vibrator 10, and thus a space required to provide the access code 21 in the vibrator group holding member 20 may be small. Therefore, according to the vibrator group manufacturing method of the first exemplary embodiment, even when the vibrator group 1 includes the vibrators arranged in a matrix and the vibrators 10 are made small, a space for providing the access code 21 in the vibrator group holding member 20 can be easily secured, and thus it is possible to manufacture the vibrator group 1 at low cost.

Further, according to the vibrator group manufacturing method of the first exemplary embodiment, the vibrator group 1 is formed by the vibrator group forming process S10 described above, and thus it is easy to assemble the vibrators 10. In addition, since the vibrator group 1 includes vibrators arranged in a matrix in a state of being divided into individual pieces, it is not also necessary to rearrange the vibrators 10, and thus it is possible to manufacture the vibrator group 1 at low cost.

### 1-2. Oscillator Manufacturing Method

Next, an oscillator manufacturing method according to the first exemplary embodiment will be described by taking an oscillator manufacturing method using the vibrator group 1, obtained by applying the manufacturing method illustrated in FIG. 1, as an example. FIG. 14 is a flowchart illustrating an example of a procedure of the oscillator manufacturing method according to the first exemplary embodiment. For example, a vibrator manufacturer supplies the vibrator group 1 manufactured by the manufacturing method illustrated in FIG. 1 to an oscillator manufacturer, and the oscillator manufacturer manufactures an oscillator by a procedure of FIG. 14. As illustrated in FIG. 14, in this exemplary embodiment, first, the vibrator group 1 including the first to n-th (n≥2) vibrators 10 arranged in a matrix and first to n-th integrated circuit devices (IC chips) are prepared (step S50). As described above, for example, the vibrator group 1 is obtained by the vibrator group forming process S10 of FIG. 1 (steps S100 to S130 in FIG. 2). In addition, each of the first to n-th integrated circuit devices includes a circuit that oscillates the first to n-th vibrators 10.

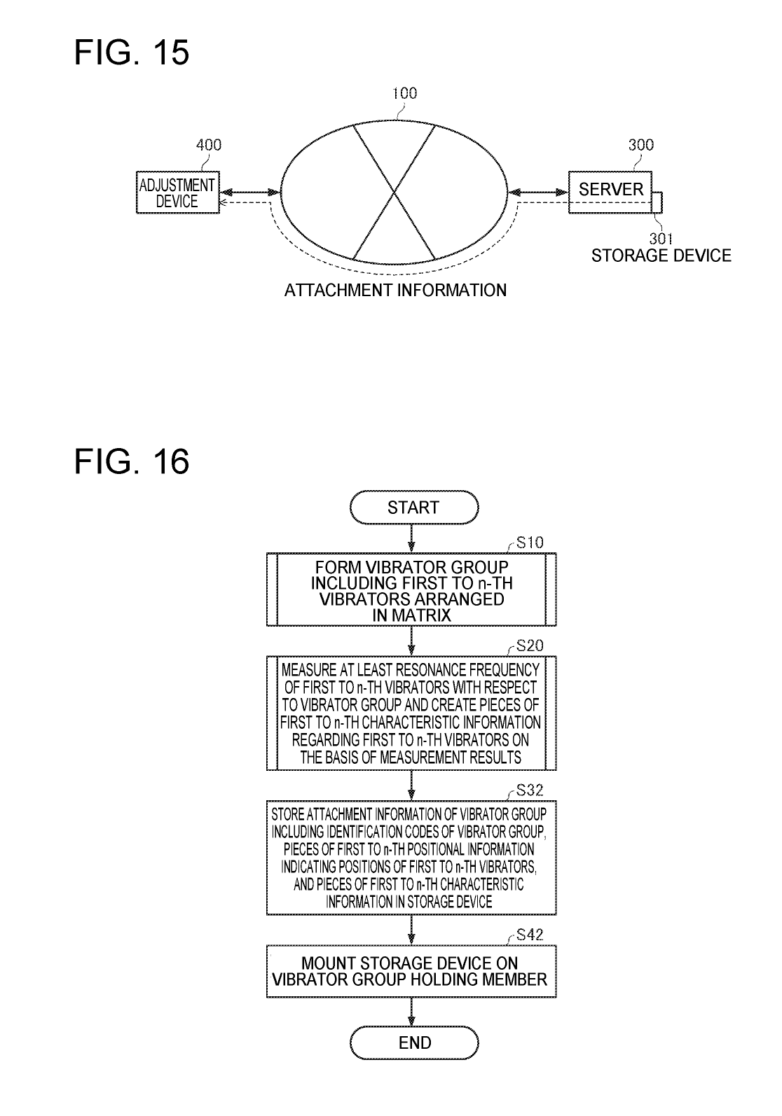

Next, attachment information of the vibrator group 1 including pieces of first to n-th positional information indicating the positions of the first to n-th vibrators 10 and pieces of first to n-th characteristic information based on measurement results of resonance frequencies of the first to n-th vibrators 10 is acquired using an access code provided in the vibrator group holding member 20 (step S60). As illustrated in FIG. 15, the attachment information of the vibrator group 1 is stored in the storage device 301 accessible through the communication network 100 (for example, the Internet or a LAN), that is, the storage device 301 provided in the server 300 connected to the communication network 100 by the attachment information storage process S30 of FIG. 1. The adjustment device 400 acquires the attachment information of the vibrator group 1 which is stored in the storage device 301 through the communication network 100, using an access code which is read by a bar code reader or the like or is input from a keyboard or the like.

Next, a k-th vibrator 10 is selected from the vibrator group 1, k being an integer of 1 to n, and the k-th vibrator 10 and the k-th integrated circuit device are integrated with each other (step S70). Specifically, an oscillator is configured by connecting predetermined two terminals (electrodes) of the k-th integrated circuit device and two terminals (two electrodes 131 (see FIG. 7)) of the k-th vibrator 10 to each other to integrate the four terminals with each other.

Finally, k-th characteristic information (characteristic information regarding the k-th vibrator 10) is selected based on k-th (k is an integer of 1 to n) positional information (positional information regarding the k-th vibrator 10) included in the attachment information acquired in step S60, and frequency adjustment of an output signal of the k-th integrated circuit device is performed based on the k-th characteristic information (step S80). For example, in the examples of FIGS. 10 and 11, the value of positional information regarding the first vibrator 10 of which the XY coordinates are (1,16) is 0116, and the adjustment device 400 selects first characteristic information associated with 0116 which is the value of the positional information and adjusts the oscillation frequency of an oscillator, having the first vibrator 10 and the first integrated circuit device integrated with each other, which is obtained by step S70. For example, the adjustment device 400 adjusts a load capacity C_{L} built-in or externally attached to the first integrated circuit in accordance with a difference between a resonance frequency f1 of the first vibrator 10 and a target frequency at a temperature T1 included in the first characteristic information and equivalent circuit constants (or information for specifying the above-described Expression (3)), and brings the resonance frequency f1 close to the target frequency. In addition, the adjustment device 400 may adjust the oscillation frequency by calculating a coefficient value of a correction expression for bringing the oscillation frequency of the oscillator close to the target frequency in a desired temperature range based on differences between the resonance frequencies f2 to fm of the first vibrator 10 at the temperatures T2 to Tm and the resonance frequency f1 at the temperature T1 included in the first characteristic information or based on coefficient values of the above-described Expression (2) and by setting the coefficient values in a temperature compensation circuit built into the first integrated circuit. Alternatively, the adjustment device 400 may adjust the oscillation frequency by setting coefficient values of a correction expression included in the first characteristic information in the temperature compensation circuit built into the first integrated circuit.

An oscillator to be manufactured by the procedure of FIG. 14 may be a simple oscillator (Simple Packaged Crystal Oscillator (SPXO) or the like) which does not perform temperature compensation and temperature control, or may be an oscillator with a temperature compensation function (Temperature Compensated Crystal Oscillator (TCXO) or the like), an oscillator with a temperature control function (Oven Controlled Crystal Oscillator (OCXO) or the like), an oscillator with a frequency control function (Voltage Controlled Crystal Oscillator (VCXO) or the like), or the like.

According to the above-described oscillator manufacturing method of the first exemplary embodiment, it is possible to integrate the vibrators 10 included in the vibrator group 1 and the integrated circuit devices with each other, acquire attachment information stored in the storage device 301 through the communication network 100 using the access code 21 provided in the vibrator group holding member 20, and perform frequency adjustment of an oscillator with a high level of accuracy using characteristic information selected based on positional information of the vibrators 10 which is included in the attachment information. In addition, according to the oscillator manufacturing method of the first exemplary embodiment, the attachment information including the positional information and the characteristic information regarding the vibrators 10 arranged in a matrix and constituting the vibrator group 1 is acquired from the storage device 301, and thus it is not necessary to use a more expensive vibrator group in which a code indicating the characteristic information is printed on each vibrator or in the vicinity of the vibrator. Therefore, according to the oscillator manufacturing method of the first exemplary embodiment, it is possible to realize a high-accuracy oscillator at low cost.

### 2. Second Exemplary Embodiment

Hereinafter, with regard to a second exemplary embodiment, the same components as those in the first exemplary embodiment are denoted by the same reference numerals and signs, the same description as that in the first exemplary embodiment will be omitted or simplified, and contents different from those in the first exemplary embodiment will be mainly described.

FIG. 16 is a flowchart illustrating an example of a procedure of a vibrator group manufacturing method according to the second exemplary embodiment. For example, a vibrator manufacturer manufactures a vibrator group 1 by the procedure of FIG. 16. As illustrated in FIG. 16, in the second exemplary embodiment, first, a vibrator group forming process S10 and a characteristic information creating process S20 which are the same as those in the first exemplary embodiment are performed. For example, the vibrator group forming process S10 maybe performed by the procedure (steps S100 to S130) shown in the flowchart of FIG. 2. In addition, for example, the characteristic information creating process S20 may be performed by the procedure (steps S200 to S220) of FIG. 8.

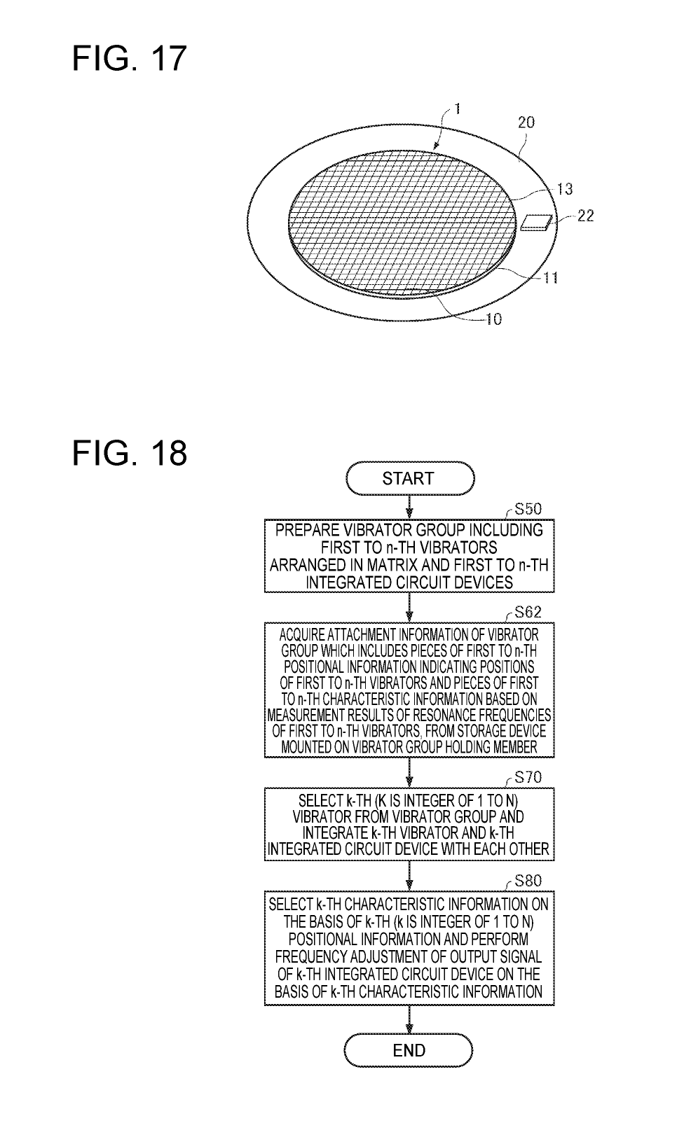

Next, a process of storing attachment information of the vibrator group 1 in a storage device 22 (see FIG. 17 to be described later) (attachment information storage process) S32 is performed. The attachment information includes attachment information (information to be attached to the vibrator group 1) including identification information regarding the vibrator group 1 which is obtained in the vibrator group forming process S10, pieces of first to n-th positional information indicating the positions of first to n-th vibrators 10 (positions within the vibrator group), and pieces of first to n-th characteristic information (first to n-th characteristic information based on measurement results of resonance frequencies of the first to n-th vibrators 10) which is obtained in the characteristic information creating process S20. In this exemplary embodiment, the storage device 22 is a small-sized memory chip. The attachment information of the vibrator group 1 is created by, for example, an inspection device 200, is transmitted to the storage device 22 (memory chip) from the inspection device 200, and is stored in the storage device 22. Meanwhile, the attachment information of the vibrator group 1 is the same as that in the first exemplary embodiment, and thus a description thereof will be omitted.

Finally, a process of mounting the storage device 22, having the attachment information stored therein in the attachment information storage process S32, on a vibrator group holding member 20 (storage device mounting process) S42 is performed. FIG. 17 illustrates an example of the vibrator group 1 held by the vibrator group holding member 20 having the storage device 22 mounted thereon by the storage device mounting process S42. For example, the storage device 22 may be bonded to the vibrator group holding member 20 using an adhesive, or may be attached to the vibrator group holding member 20 by a seal or a tape.

In the above-described vibrator group manufacturing method of the second exemplary embodiment, the vibrator group 1 held by the vibrator group holding member 20 and having the first to n-th vibrators 10 arranged in a matrix is manufactured, and attachment information including pieces of first to n-th positional information respectively indicating the positions of the first to n-th vibrators 10 within the vibrator group 1 and pieces of first to n-th characteristic information associated with the pieces of first to n-th positional information is created. In addition, the attachment information is stored in the storage device 22, and the storage device 22 is mounted on the vibrator group holding member 20. Therefore, according to the vibrator group manufacturing method of the second exemplary embodiment, a code indicating characteristic information is not required to be printed on each vibrator 10 or in the vicinity of the vibrator, and thus it is possible to manufacture the vibrator group 1 at low cost. In addition, when a vibration device such as an oscillator or a vibration type sensor is manufactured using the vibrator 10 included in the vibrator group 1 manufactured by the vibrator group manufacturing method according to the second exemplary embodiment, it is possible to acquire the attachment information of the vibrator group 1 from the storage device 22 and to adjust the vibration device with a high level of accuracy using the characteristic information regarding the vibrator 10 selected based on the positional information. Therefore, according to the vibrator group manufacturing method of the second exemplary embodiment, it is possible to realize the vibrator group 1 usable for the manufacture of a high-accuracy vibration device at low cost.

FIG. 18 is a flowchart illustrating an example of a procedure of an oscillator manufacturing method according to the second exemplary embodiment. For example, a vibrator manufacturer supplies the vibrator group 1 manufactured by the manufacturing method illustrated in FIG. 16 to an oscillator manufacturer, and the oscillator manufacturer manufactures an oscillator by a procedure of FIG. 18. As illustrated in FIG. 18, in the second exemplary embodiment, first, step S50 which is the same step as that in the first exemplary embodiment is performed.

Next, the attachment information of the vibrator group 1 which includes the pieces of first to n-th positional information indicating the positions of the first to n-th vibrators 10 and the pieces of first to n-th characteristic information based on the measurement results of the resonance frequencies of the first to n-th vibrators 10 is acquired from the storage device 22 mounted on the vibrator group holding member 20 (step S62). The attachment information of the vibrator group 1 is stored in the storage device 22 mounted on the vibrator group holding member 20, and an adjustment device 400 acquires the attachment information of the vibrator group 1 which is stored in the storage device 22.

Next, step S70 which is the same step as that in the first exemplary embodiment is performed, and finally, step S80 which is the same step as that in the first exemplary embodiment is performed.

According to the above-described oscillator manufacturing method of the second exemplary embodiment, it is possible to integrate the vibrators 10 included in the vibrator group 1 and the integrated circuit devices with each other, acquire attachment information from the storage device 22 mounted on the vibrator group holding member 20, and perform frequency adjustment of an oscillator with a high level of accuracy using characteristic information selected based on positional information of the vibrators 10 which is included in the attachment information. In addition, according to the oscillator manufacturing method of the second exemplary embodiment, the attachment information including the positional information and the characteristic information regarding the vibrators 10 arranged in a matrix and constituting the vibrator group 1 is acquired from the storage device 301, and thus it is not necessary to use a more expensive vibrator group in which a code indicating the characteristic information is printed on each vibrator or in the vicinity of the vibrator. Therefore, according to the oscillator manufacturing method of the second exemplary embodiment, it is possible to realize a high-accuracy oscillator at low cost.

### 3. Modification Example

For example, in the above-described exemplary embodiments, the vibrator group holding member 20 is a dicing tape (wafer tape), but may be a tray. That is, the separate first to n-th vibrators 10 constituting the vibrator group 1 may be arranged in a matrix on the tray, and an access code 21 may be provided on the tray or the storage device 22 may be provided on the tray.

In the above-described exemplary embodiments, the attachment information of the vibrator group 1 may include information regarding a representative value of resonance frequencies f2 to fm of the first to n-th vibrators 10 or a representative value of temperature compensation information (a coefficient value of the above-described Expression (2) or a coefficient value of a correction expression) and a variation compensation value (an upper limit value and a lower limit value of a deviation with respect to the representative value), as information based on temperature dependence of resonance frequencies of the first to n-th vibrators 10. As the representative value, a median value, an average value, or the like is appropriately selected. In addition, the attachment information of the vibrator group 1 may include information regarding a representative value of equivalent circuit constants of the first to n-th vibrators 10 and a variation compensation value (an upper limit value and a lower limit value of a deviation with respect to the representative value). In this manner, it is possible to reduce the amount of data of the attachment information.

In the above-described second exemplary embodiment, the storage device 22 (memory chip) is not mounted on the vibrator group holding member 20, and for example, a vibrator manufacturer may supply the vibrator group 1 and the storage device 22 as a set to an oscillator manufacturer.

In the above-described exemplary embodiments, a code indicating a position within the vibrator group 1 may be marked on each vibrator 10 so that characteristic information regarding the vibrators 10 can be correctly selected even when the positions of the vibrators 10 are changed. Since the code indicating the position within the vibrator group 1 can be realized by characters or symbols of approximately two digits, the code maybe marked even when the vibrator 10 is made small. Meanwhile, in order to reduce the influence of the vibrator 10 on mounting, it is preferable that the code is marked on a surface on a side where the electrode 131 of the vibrator 10 is not provided.

The invention is not limited to this exemplary embodiment, and various modifications can be made without departing from the scope of the invention.

The above-described exemplary embodiments and modification example are examples, and the invention is not limited thereto. For example, it is also possible to appropriately combine the exemplary embodiments and the modification example.

The invention includes substantially the same configurations (for example, configurations having the same functions, methods and results, or configurations having the same objects and effects) as the configurations described in the embodiments. In addition, the invention includes a configuration obtained by replacing non-essential portions in the configurations described in the embodiments. In addition, the invention includes a configuration that exhibits the same operational effects as those of the configurations described in the embodiment or a configuration capable of achieving the same objects. In addition, the invention includes a configuration obtained by adding known techniques to the configurations described in the embodiments.

The entire disclosure of Japanese Patent Application No. 2017-217391, filed Nov. 10, 2017 is expressly incorporated by reference herein.

What is claimed is:

1. A vibrator group manufacturing method comprising:
measuring resonance frequencies of first to n-th vibrators arranged in a matrix with respect to a vibrator group including the first to n-th vibrators, n being an integer of 2 or greater; and
storing attachment information of the vibrator group in a storage device, the attachment information including identification information imparted to the vibrator group, pieces of first to n-th positional information indicating positions of the first to n-th vibrators, and pieces of first to n-th characteristic information based on measurement results of the resonance frequencies of the first to n-th vibrators.

2. The vibrator group manufacturing method according to claim 1,
wherein the attachment information stored in the storage device is accessible through a communication network, and
an access code for accessing the attachment information is provided in a vibrator group holding member that holds the vibrator group.

3. The vibrator group manufacturing method according to claim 1, further comprising:
mounting the storage device on a vibrator group holding member that holds the vibrator group.

4. The vibrator group manufacturing method according to claim 1,
wherein the pieces of first to n-th characteristic information includes measurement results of resonance frequencies of the first to n-th vibrators at a predetermined temperature.

5. The vibrator group manufacturing method according to claim 1, further comprising:
measuring resonance frequencies of the first to n-th vibrators at a plurality of different temperatures,
wherein the pieces of first to n-th characteristic information includes information based on temperature dependence of the resonance frequencies of the first to n-th vibrators.

6. The vibrator group manufacturing method according to claim 1, further comprising:
preparing a vibration piece mounting substrate, first to n-th vibration pieces, and a sealing substrate;
mounting the first to n-th vibration pieces on the vibration piece mounting substrate in a matrix;
bonding the sealing substrate to the vibration piece mounting substrate on which the first to n-th vibration pieces are mounted; and
cutting the vibration piece mounting substrate having the sealing substrate bonded thereto to form the vibrator group including the first to n-th vibrators respectively including the first to n-th vibration pieces.

7. An oscillator manufacturing method comprising:
preparing a vibrator group including first to n-th vibrators arranged in a matrix, and first to n-th integrated circuit devices;
acquiring attachment information of the vibrator group which includes pieces of first to n-th positional information indicating positions of the first to n-th vibrators and pieces of first to n-th characteristic information based on measurement results of resonance frequencies of the first to n-th vibrators;
selecting the k-th vibrator from the vibrator group to integrate the k-th vibrator and the k-th integrated circuit device with each other, k being an integer of 1 to n; and
selecting the k-th characteristic information based on the k-th positional information to perform frequency adjustment of an output signal of the k-th integrated circuit device based on the k-th characteristic information.

8. The oscillator manufacturing method according to claim 7,
wherein the attachment information is stored in a storage device accessible through a communication network, and
the attachment information stored in the storage device is acquired using an access code provided in a vibrator group holding member that holds the vibrator group.

9. The oscillator manufacturing method according to claim 7,
wherein the attachment information is stored in a storage device mounted on a vibrator group holding member that holds the vibrator group.
